(19) United States
(12) Patent Application Publication
(10) Pub. No.: US 2011/0139486 A1
(43) Pub. Date: Jun. 16, 2011

(54) ELECTRICAL INSULATING COATING AND METHOD FOR HARSH ENVIRONMENT

(75) Inventors: William T. Carter, Galaway, NY (US); Scott A. Weaver, Ballston Lake, NY (US); Russell S. Miller, Ballston Spa, NY (US)

(73) Assignee: General Electric Company

(21) Appl. No.: 12/639,521

(22) Filed: Dec. 16, 2009

(51) Int. Cl. H01B 3/10; B05D 5/12; B05D 1/00; C23C 14/34

(52) U.S. Cl. 174/110 A; 174/137 B; 427/123; 427/580; 204/192.1

(57) ABSTRACT

A thin electrical insulating coating and method for application is provided for a copper surface. The electrical insulating coating includes a bond coat layer of titanium, nickel, or NiCrAlY forming a metallurgical bond with the copper surface and an insulating layer of alumina or tantala applied to the bond coat layer. An insulating layer does not firmly adhere to copper under harsh environmental conditions such as an electroslag refining process when applied directly to the copper. However, when bond coat layer is applied between the copper and the insulating layer, it forms a strong bond adhering bond for the harsh environment.

### STATEMENT REGARDING FEDERALLY SPONSORED RESEARCH & DEVELOPMENT

This invention was made with Government support under contract number 70NANB1H3042 awarded by National Institute of Standards and Technology. The Government has certain rights in the invention.

### CROSS REFERENCE TO RELATED APPLICATIONS

The present invention is related to the following application: Docket 161959-2, assigned to General Electric and filed on Dec. 16, 2009.

### BACKGROUND OF THE INVENTION

This invention relates generally to electrical insulation for electrical conductors, and more specifically to electrical insulation for electrical conductors operating under harsh external environments.

An insulator is a material or object that prevents the flow of electrical charges, thereby preventing the flow of an electrical current. While an electrical insulating material must be capable of withstanding the voltage and frequency of the power source which they are intended to insulate, the material must also be suitable for environment in which is to operate. These environmental factors include temperature, mechanical wear, and chemical composition of the surroundings. Further, while maintaining the appropriate electrical insulating protection characteristics, the insulating material must also not adversely impact other materials or components to which it contacts or to which it is exposed.

Exposure to harsh environments requires insulating materials that can withstand the environment. An example of a harsh environment is that which is encountered in metal refining processes.

Electroslag refining (ESR) is a process used to melt and refine a wide range of alloys for removing various impurities. Typical alloys, which may be effectively refined, using electroslag refining include those based on nickel, cobalt, zirconium titanium, or iron. The initial, unrefined alloys are typically provided in the form of an ingot which has various defects or impurities which are desired to be removed during the relining process to enhance metallurgical properties, including grain size and microstructure, for example.

In a conventional electroslag apparatus, the ingot is connected to a power supply and defines an electrode that is suitably suspended in a water-cooled crucible containing a suitable slag corresponding with the specific alloy being refined. The slag is heated by passing an electrical current from the electrode through the slag into the crucible and is maintained at a suitable high temperature for melting the lower end of the ingot electrode. As the electrode melts, a refining action takes place with oxide inclusion in the ingot melt being exposed to the liquid slag and dissolved therein. Droplets of the ingot melt fall through the slag by gravity and are collected in a liquid melt pool at the bottom of the crucible.

The refined melt may be extracted from the crucible by a conventional induction-heated, segmented, cold-walled induction heated guide (CIG). The refined melt extracted from the crucible in this matter provides an ideal liquid metal source for various solidification processes including spray deposition.

The electroslag apparatus may be conventionally cooled to form a solid slag skull on the surface for bounding the liquid slag and preventing damage to the crucible itself as well as preventing contamination of the ingot melt from contact with the patent material of the crucible. The bottom of the crucible typically includes a water-cooled, copper cold hearth against which a solid skull of the refined melt forms for maintaining the purity of the collected melt at the bottom of the crucible. The CIG discharge guide tube or downspout below the hearth is also typically made of copper and is segmented and water-cooled for also allowing the formation of a solid skull of the refined melt for maintaining the purity of the melt as it is extracted from the crucible.

The cold heath and the guide tube of the conventional electroslag refining apparatus are relatively complex in structure. The guide tube typically joins the cold heath in a conical funnel with the induction heating coils surrounding the outer surface oldie funnel and the downspout through which the metal flows.

A plurality of water-cooled induction heating electrical conduits surround the guide tube for inductively heating the melt for controlling the discharge flow rate of the melt through the tube. Alternating currents in the induction heating electrical conduits, surrounding the copper funnel segments, induce alternating eddy currents within the copper segments. In turn the alternating eddy currents within the copper funnel segments of the guide tube induce currents within the liquid metal in the flow path through the guide tube, thereby transferring energy to the liquid metal. The energy provided heats the liquid metal heats, influencing the flow characteristics of the metal through the funnel.

However, unless the copper segments of the guide tube are electrically insulated from the liquid metal, some of the induced currents within the copper segments of the guide tube will flow into the liquid metal, thereby reducing the transfer of energy through induction into the liquid metal. Therefore, it is desirable to electrically insulate the copper segments of the guide tube from the liquid metal flowing through the guide tube.

Further, an insulating layer on the copper segments must sustain high thermal gradients and thermal shock imposed during the heating and cooling of the liquid metal. The insulating layer must be robust, but at the same time thin so as not to interfere with the liquid metal flow taking place in a specially shaped flow path of the funnel.

Separate layers of electrical insulation have been applied between copper segments (U.S. Pat. No. 5,992,503). However, no electrical insulation has been employed between the copper segments and the liquid metal pool, owing to the harsh environment. Conventional electrical insulators cannot withstand the harsh environment of this application. Other unconventional insulations, such as plasma sprayed alumina, are thick and friable. Such insulators, which crack or crumble when in contact with the refined flow of the liquid metal, are unacceptable for use because they introduce the insulating material as an impurity into the refined liquid metal.

Accordingly, there is a need to provide a robust electrical insulating material for conducting materials, which operate in severe environments such as the ESR process. At the same time an electrical insulating material may not be used which contaminates the surrounding environment.

### BRIEF DESCRIPTION OF THE INVENTION

Briefly in accordance with one aspect of the present invention, a thin electrical insulating coating is provided for a copper surface. The electrical insulating coating includes a bond coat layer of titanium, nickel, or NiCrAlY forming a metallurgical bond with the copper surface and an insulating layer of alumina or tantala applied to the bond coat layer.

In accordance with another aspect of the present invention, a method for applying an electrical insulating coating to a copper surface is provided. The method for providing the electrical insulating coating to the copper surface includes applying a bond coat layer, polishing the layer; and applying an insulating layer.

A further aspect of the present invention provides an article of manufacture. The article of manufacture includes a base material comprised of copper and a thin electrical insulating coating for a copper surface. The electrical insulating coating includes a bond coat layer forming a metallurgical bond with the copper surface and an insulating layer above the bond coat layer.

### BRIEF DESCRIPTION OF THE DRAWING

These and other features, aspects, and advantages of the present invention will become better understood when the following detailed description is read with reference to the accompanying drawings in which like characters represent like parts throughout the drawings, wherein:

FIG. 1 illustrates a photomicrograph of the inventive coating applied to a copper surface before and after exposure to harsh liquid metal; and

FIG. 2 illustrates a flowchart of a method for applying an electrical insulating coating to a copper surface.

### DETAILED DESCRIPTION OF THE INVENTION

Copper is an electrically and thermally conductive material. Some applications require an electrically insulating layer on the surface of the copper to avoid conduction of electricity outside of the copper. An example of such an application is the cold-walled-induction guide, which is a water-cooled, induction-heated guide tube for pouring liquid metal. The induction heating of the CIG requires that the device be radially segmented. A surrounding induction coil induces a current in the CIG, which then induces a heating current in the outward flowing metal stream. It is important that electric current that flows through the copper is prevented from flowing into the liquid metal, because if current does so, the efficiency of the unit is lost. An insulating layer is required. For this application, the requirements of the insulating layer were harsh: it must sustain high thermal gradients and thermal shock; it must be robust; and it must be thin.

The introduction of standard ceramic insulators is regarded as unacceptable. The bulk ceramics, act as a thermal insulator and the surface temperature of these materials approach the melt temperature where chemical attack, especially by titanium, is thermodynamically favorable. Furthermore, ceramics can liberate unacceptably large particles after chemical attack or as the result of thermal stress or shock. However, with a dielectric strength of about 20 V per micron, very thin films of alumina can provide the necessary electrical isolation, and thin films remain thermodynamically stable at copper surface temperatures. Tantala is similarly appropriate. Sputtering and chemical vapor deposition (CVD) can both yield coatings that are 100% dense and free of defects.

Direct application of existing coating technology, which was developed for superalloys and stainless steel substrates, to copper surfaces proved unsuccessful, and a bond coat was required. Nickel, NiCrAlY and titanium coating on copper were demonstrated as bond coats, and the thin coatings did not affect electromagnetic performance of the CIG. Sputtered nickel coatings of approximately 1 micron and cathodic arc coatings of titanium of several tens of microns were used.

Sputtered alumina and CVD deposited tantala coatings on the bond coat were tested as insulating layers. Sputtered alumina on sputtered nickel is a well-developed technology and dominated our testing. However, sputtering is directional and requires precise surface preparation, posing some difficulties in coating articles of manufacture with curved surfaces. CVD deposition avoids these problems and was demonstrated to be compatible with brazed articles of manufacture such as CIG components despite the high temperatures used during coating.

According to one aspect of the present invention, a thin electrical insulating coating for copper surfaces is provided. The coating is produced by first applying about a 50 micron bonding layer of titanium, nickel or NiCRAlY using a cathodic arc deposition process or by sputtering. This layer is polished and topped with a 5 to 10 micron layer of alumina, or a 1-10 micron layer of tantala. The resulting coating is robust in that it can take thermal shock without separating from the copper substrate. Methods for applying, the insulating layer include sputtering or by chemical vapor deposition.

The bonding layer forms a robust metallurgical bond with the copper. The alumina or tantala, which does not bond well directly to copper, is applied to the titanium layer, forming another robust layer. The resulting layer is thin, but electrically insulating. The coating of the present invention functions well when conventional insulators cannot take the exemplary environment of the ESR or other harsh applications. Unlike other conventional insulations such as plasma sprayed alumina that is thick and friable, the insulating coating of the present invention is thin and adheres strongly to the applied bonding layer. Consequently, the inventive coating does not corrupt the refined metal of the exemplary ESR process or the external environments in harsh conditions for other applications. It has further been demonstrated that the process can be applied to copper alloys. For example, the coating process described has been applied to copper-silver braze alloys, and to oxide dispersion strengthened copper. These materials have significant advantages in construction of items of manufacture, such as a cold-walled induction guide.

According to another aspect of the present invention a method for application of the inventive coating is provided. The steps of the method include applying a bond coat layer metal, polishing the layer and applying a layer of insulating coating.

The step of applying a bond coat layer of titanium, nickel or NiCrAlY includes applying the layer by a cathodic arc deposition process or by sputtering. The step of applying a bond coat layer of metal by a cathodic arc deposition process may further include applying about 50 microns of metal.

The step of applying a layer of alumina or tantala may include the step of applying a layer of alumina of about 5-10 microns or tantala of about 1-10 microns. The step of applying a layer of alumina or tantala may also include applying the layer of alumina or tantala by sputtering. The step of applying a layer of alumina or tantala may also include applying the layer of alumina or tantala by chemical vapor deposition. Chemical vapor deposition (CVD) may be preferred in applications where the article of manufacture to which the insulating layer is applied has curved surfaces, as the CVD process facilitates application on these surfaces. Copper components have been constructed and coated with the inventive coating technique. Testing was performed with coatings of a 5-micron alumina layer and a 10-micron alumina layer. The components were tested under actual working conditions of an exemplary ESR, exposed to the liquid metal flow. The coating showed no visible degradation due to service. Further testing with coatings of a 5-micron tantala layer under actual working conditions of an exemplary ESR, exposed to the liquid metal flow, showed no visible degradation due to service.

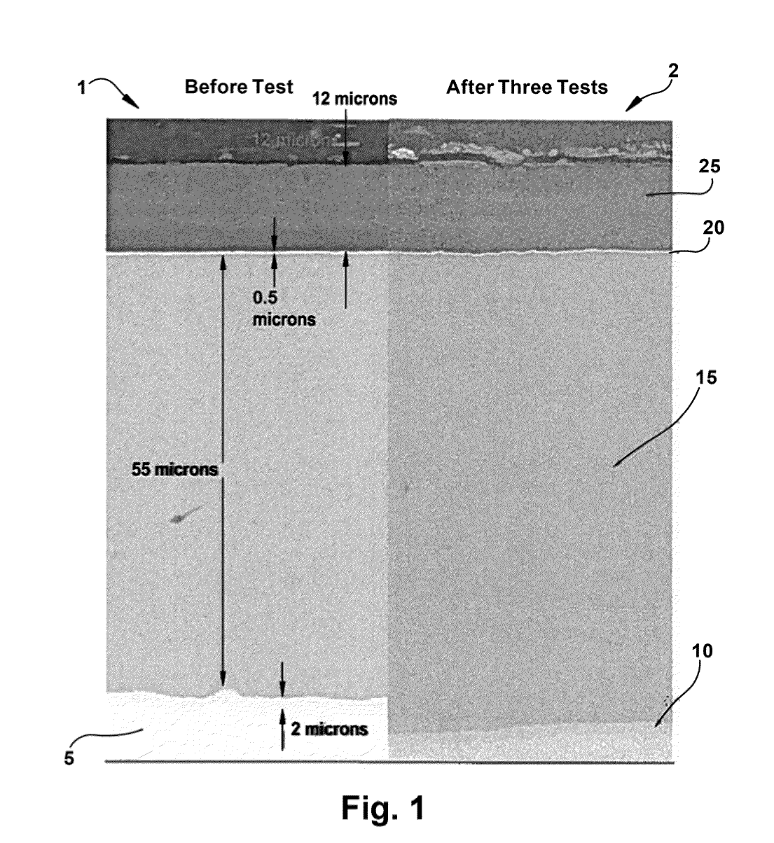

A scanning electron micrograph of the untested and tested inventive insulating coating is shown in FIG. 1. The following layers are evident: a copper substrate 5; a Titanium-Copper alloy layer 10 of about 2 microns; a titanium layer 15 of about 55 microns; 4) a sputtered NiCr layer 20 of about 0.5 microns; and a sputtered alumina layer 25 of about 12 microns. These layers are shown before service on the left side of FIG. 1 and after service on the right side of FIG. 1. No visible degradation occurred.

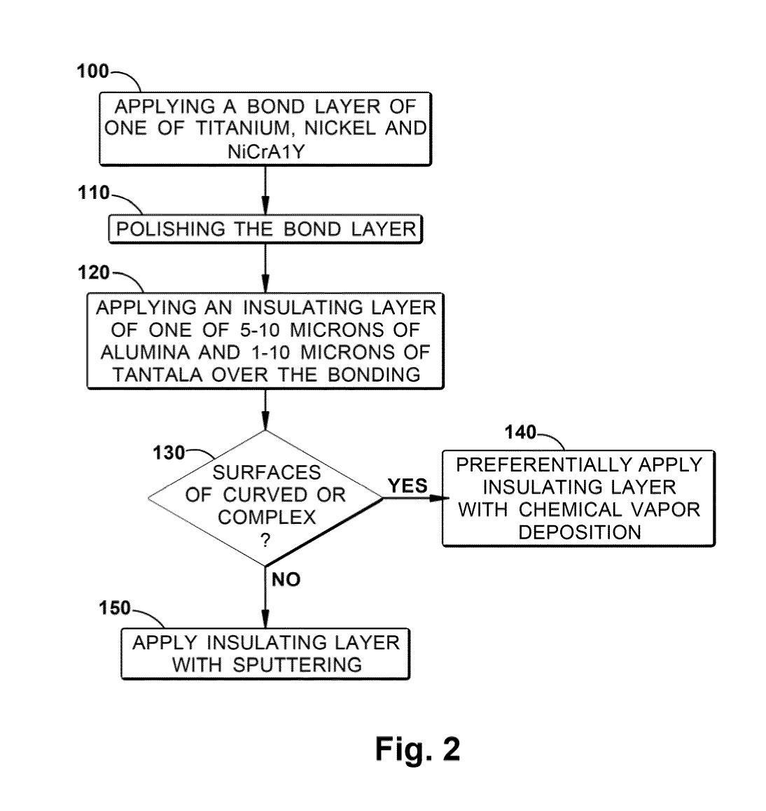

FIG. 2 illustrates a flowchart of a method for applying an electrical insulating coating to a copper surface. The method includes in step 100 applying a bond layer of titanium, nickel or NiCrAlY of about 50 microns. The bond layer is polished in step 110. Step 120 applies a layer of one of alumina of about 5-10 microns thickness or tantala of about 1-10 microns thickness. In step 130 a determination is made as to whether the surfaces of the article of manufacture are curved or complex. Step 140 provides applying the insulating layer with a CVD process if the surfaces are curved or complex. Step 150 applies the alumina layer with a sputtering process if the surfaces are not curved or complex.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A thin electrical insulating coating for a surface of one of copper and a copper alloy, the electrical insulating coating comprising:
a bond layer of one of titanium, nickel and NiCrAlY forming a metallurgical bond with the surface; and
an insulating layer of one of alumina and tantala above the bond layer.

2. The electrical insulating coating for the surface of claim 1, wherein the bond layer comprises about a 50 micron layer.

3. The electrical insulating coating for the surface of claim 1, wherein the bond layer is polished.

4. The electrical insulating coating for the surface of claim 2, wherein the insulating layer comprises about a 5 to 10 micron layer of alumina.

5. The electrical insulating coating for the surface of claim 2, wherein the insulating layer comprises about a 1 to 10 micron layer of tantala.

6. The electrical insulating coating for the surface of claim 3, wherein the insulating layer comprises a sputtered layer.

7. The electrical insulating coating for the surface of claim 3, wherein the insulating layer comprises a chemical vapor deposition layer.

8. A method for providing an electrical insulating coating for one of a copper surface and a copper alloy surface, the method comprising:
applying a bonding layer of one of titanium, nickel and NiCrAlY;
polishing the bonding layer; and
applying an insulating layer of one of alumina and tantala.

9. The method of claim 8, wherein the step of applying a bonding layer comprises one of a cathodic arc deposition process and sputtering.

10. The method of claim 8, wherein the step of applying a bonding layer comprises applying about 50 microns of titanium.

11. The method of claim 10 wherein the step of applying an insulating layer comprises applying one of about 5-10 microns of alumina and about 1-10 microns of tantala.

12. The method of claim 11, wherein the step of applying an insulating layer comprises sputtering.

13. The method of claim 11, wherein the step of applying an insulating layer comprises chemical vapor deposition.

14. An article of manufacture comprising:
a base material comprised of one of copper and a copper alloy; and
a thin electrical insulating coating for a surface of the article of manufacture, the electrical insulating coating comprising a bonding layer of one of titanium, nickel and NiCrAlY forming a metallurgical bond with the copper surface; and an insulating layer of one alumina and tantala above the bonding layer.

15. The article of manufacture according to claim 14, wherein the bonding layer of the electrical insulating coating comprises about a 50 micron layer.

16. The article of manufacture according to claim 14, wherein the bonding layer of the electrical insulating coating comprises a polished surface.

17. The article of manufacture according to claim 14, wherein the insulating layer comprises one of about a 5 to 10 micron layer of alumina and about a 1 to 10 micron layer of tantala.

18. The article of manufacture of claim 17, wherein the insulating layer comprises a sputtered layer.

19. The article of manufacture of claim 17, wherein the insulating layer comprises a chemical vapor deposition layer.

20. The article of manufacture of claim 1 wherein the electrical insulating coating is selectively applied to designated surfaces of the article of manufacture, the designated surfaces being surfaces exposed to harsh environments.
